(19) United States
(12) Patent Application Publication
(10) Pub. No.: US 2005/0277292 A1
(43) Pub. Date: Dec. 15, 2005

(54) Method for fabricating low resistivity barrier for copper interconnect

(76) Inventors: Chao-Hsien Peng, Hsinchu City (TW); Ching-Hua Hsieh, Hsinchu City (TW); Shau-Lin Shue, Hsinchu City (TW)

Correspondence Address: THOMAS, KAYDEN, HOSTEMEYER & RISLEY LLP, 100 GALLERIA PARKWAY, SUITE 1750, ATLANTA, GA, 30339, US

(21) Appl. No.: 10/856,899

(22) Filed: May 28, 2004

(51) Int. Cl. H01L 21/44

(52) U.S. Cl. 438/672

(57) ABSTRACT

A method of reducing the sheet resistivity of an ALD-TaN layer in an interconnect structure. The ALD-TaN layer is treated with a plasma treatment, such as Argon or Tantalum plasma treatment, to increase the Ta/N ratio of the ALD-TaN barrier layer, thereby reducing the sheet resistivity of the ALD-TaN layer.

### BACKGROUND

The present invention relates to semiconductor fabrication, and in particular to copper interconnect with an improved barrier layer between conductors and dielectrics, and methods for fabricating the same.

Aluminum and aluminum alloys are conventionally the most widely used interconnection metallurgies for integrated circuits. However, it has become more and more important for metal conductors that form the interconnections between devices as well as between circuits in a semiconductor to have low resistivity for faster signal propagation. Copper is preferred for its low resistivity as well as resistance to electromigration (EM) and stress-avoiding properties for very and ultra large scale integrated (VLSI and ULSI) circuits.

Conventionally, copper interconnects are formed using a so-called “damascene” or “dual-damascene” fabrication process rather than conventional aluminum interconnects. Briefly, a damascene metallization process forms conductive interconnects by deposition of conductive metals, i.e. copper or copper alloy, in via holes or trenches formed in a semiconductor wafer surface. However, copper implementation suffers from high diffusivity in common insulating materials such as silicon oxide, and oxygen-containing polymers, which causes corrosion of the copper with attendant serious problems of loss of adhesion, delamination, voids, and consequent electric failure of circuitry. A copper diffusion barrier is therefore required for copper interconnects.

Semiconductor devices (e.g., transistors) or conductive elements formed in a semiconductor substrate are typically covered with insulating materials, such as oxides. Selected regions of the oxide layer are removed, thereby creating openings in the semiconductor substrate surface. A barrier layer is formed, lining the bottom and sidewalls of the openings for diffusion blocking and as an adhesion interface. A conductive seed layer, e.g. copper seed layer, is then formed upon the barrier layer. The seed layer provides a conductive foundation for a subsequently formed bulk copper interconnect layer typically formed by electroplating. After the bulk copper has been deposited excess copper is removed using, for example, chemical-mechanical polishing. The surface is then cleaned and sealed with a passivation layer or the like. Similar processes will be repeated to construct multi-level interconnects.

In addition to effectiveness against copper out-diffusion, good coverage, and good adhesion, barrier films should also be conformal, continuous, and as thin as possible to lower the resistivity between two connecting conductors.

Currently, barrier materials, e.g. tantalum nitride (TaN), are deposited using conventional physical vapor deposition (PVD) or chemical vapor deposition (CVD) techniques. The drawbacks of PVD or CVD are thickness and poor conformability of the resulting barrier materials with geometries scaled to 110 nm and below.

In recent developments, atomic layer deposition (ALD) technology has been announced for the coming generation. ALD is known for its superior conformality and improved thickness control for a variety of applications: deposition of barriers, nucleation layers, and high-k dielectric materials. ALD is a self-limiting chemisorption reaction, which means the deposition rate/cycle is determined by only the saturation time, independent of the reactant exposure time after saturation. Because of this self-limiting attribute, ALD reactions in general can occur at a lower temperature than conventional thermal CVD, enabling integration with low thermal budget process flows, e.g. copper low-k integration.

### SUMMARY

The present invention discloses an adjusting element ratio of an ALD-binary compound, i.e. a compound composed of two different elements, by which plasma treatment and the physical properties of the ALD layer may be altered. For instance, the resistivity of ALD-transition metallic nitride, such as ALD-TaN, can be reduced accordingly.

The primary object of the invention is to reduce the resistivity of the ALD-formed barrier film for copper interconnect implementation. Another object of the invention is to improve the continuity of the copper seed layer deposited on the ALD-TaN layer.

To achieve the objects, the present invention provides a method of forming a TaN barrier in an interconnect structure based on ALD technology. The ALD-TaN barrier film is plasma treated to increase Ta/N ratio of the ALD-TaN layer, thereby reducing the resistivity thereof.

A detailed description is given in the following with reference to the accompanying drawings.

### BRIEF DESCRIPTION OF THE DRAWINGS

The aforementioned objects, features and advantages of this invention will become apparent by referring to the following description with reference to the accompanying drawings, wherein:

FIGS. 1A to 1F are cross-sections showing a process flow for forming a copper interconnect in accordance with the present invention;

FIG. 2 is a chart showing the Ta/N ratio variation with various plasma treatments in accordance with one embodiment of the present invention;

FIG. 3 is a chart showing the decrease in sheet resistance of plasma-treated ALD-TaN layers with the increase of Ar treatment time in accordance with one embodiment of the present invention;

FIG. 4A is an SEM photo of a copper seed layer deposited on a non-plasma-treated TaN layer;

FIG. 4B illustrates the cross-section of FIG. 4A;

FIG. 5A is an SEM photo of a copper seed layer deposited on a Ar plasma treated TaN layer in accordance with one embodiment of the present invention; and

FIG. 5B is a cross-section of FIG. 5A.

### DESCRIPTION

It is noted that the description hereinbelow refers to various layers arranged on, above or overlying other layers, to describe the relative positions of the various layers. References to “on”, “above”, “overlying”, or other similar languages, are not limited to the interpretation of one layer immediately adjacent to another. There may be intermediate or interposing layers, coatings, or other structures present, and associated process steps present, not shown or discussed herein, but allowable without departing from the scope and spirit of the invention disclosed herein. Similar, references to structures adjacent, between or other positional references to other structures merely describe the relative positions of the structures, with or without intermediate structures.

Although ALD is one of the promising ways to form ultra-thin barrier, e.g. 10˜20 Å, for sub-130 nm device node interconnect, ALD films behave differently than conventional thicker films because they are so thin. Issues such as adhesion, interface structure, and composition should be further verified. Regarding the barrier layer, TaN, for copper interconnect, the sheet resistivity of ALD-formed TaN is still too high for implementation in copper interconnects of 0.13 μm line width or narrower. ALD-formed TaN may alone retain high resistivity. In addition, the copper seed layer formed on the ALD-formed TaN layer is not uniform, due to copper knobs thereon. The knobs indicate low copper wettability, indicating that adhesion force of copper atoms to the ALD-formed TaN layer is less than the cohesion force of copper atoms themselves.

To solve these problems, the present invention provides an adjustment element ratio of an ALD compound, and further applies the ratio to reduce resistivity of an ALD-formed TaN layer and increase wettability thereof.

ALD technology is capable of forming various binary compounds, i.e. a compound composed of two different elements, such as transition metallic nitride, TaN or TiN, used as barrier layers for interconnects. For a binary compound, the two binding elements may be broken in a plasma treatment. The two different ionized elements will react with the plasma ambiance to different degrees (for example, the recombination affinity of one element toward the ALD layer will be greater than the other). Thus, plasma treatment can be utilized to adjust the element ratio of an ALD-binary compound layer. The element ratio will be affected dominantly because the layer formed by ALD is very thin and some physical properties of the ALD-thin film will be altered as well.

In the following embodiment, the Ta/N ratio of an ALD-transition metallic nitride layer, ALD-TaN, is elevated with an Ar or a Ta plasma treatment, thus reducing the resistivity of the ALD-TaN layer. Adhesion between the TaN layer 140′ and the subsequent copper seed layer 160 is improved as well.

### Embodiment

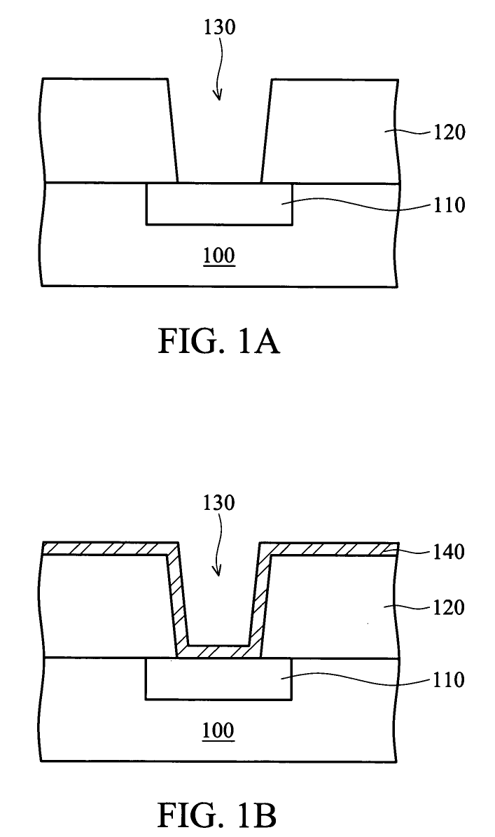

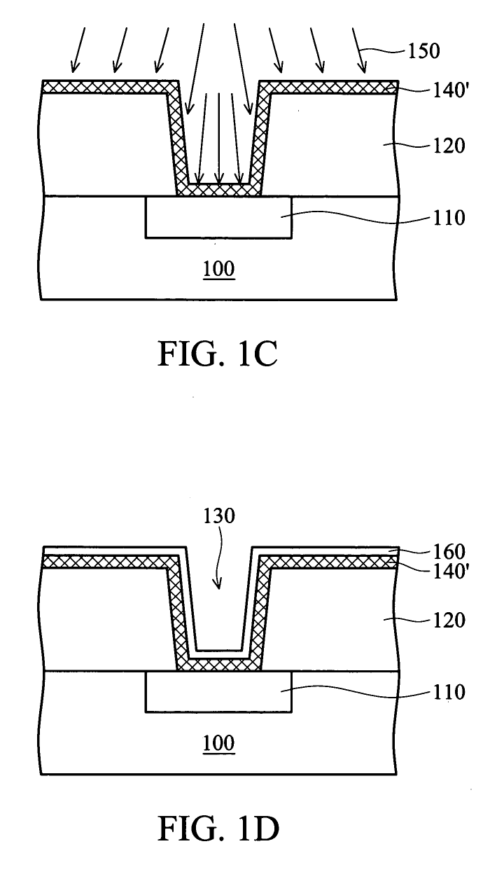

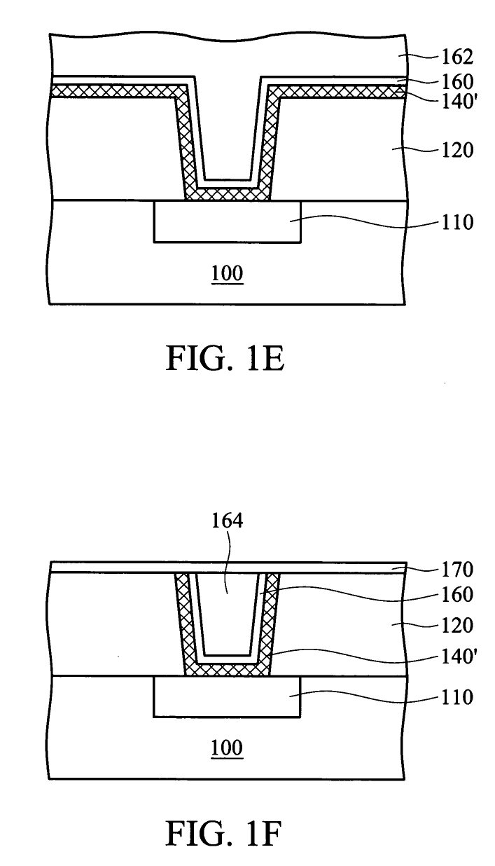

FIGS. 1A to 1F show a process flow of forming a copper interconnect according to the invention. The figures are only used to exemplify the formation of a via interconnect according to the invention. The present invention, however, is not limited thereto, but also applicable to other single or dual damascene openings as well. In FIG. 1A, a semiconductor substrate 100 is provided with an electrically conductive region 110 thereon. A dielectric layer 120, such as silicon oxide or low-k material with a dielectric constant k<3.2, is deposited on the surface of the substrate 100 and covers the conductive region 110 to a desired thickness for a via. Preferably, low-k dielectrics are introduced for 0.13 μm or narrower device node interconnect. The low-k dielectric layer 120 can comprise organic low-k materials, such as Black Diamond (organosilicate glass) provided by Applied Materials, Inc. or inorganic low-k materials such as fluorinated silica glass (FSG), SiC, SiOC, SiOCN, Hydrogen-sisequioxane (HSQ) or xerogels (one of spin-on-dielectrics). The dielectric layer 120 is patterned by photolithography and then etched to form a via opening 130. An etch stop layer, e.g. SiN, (not shown) can be optionally formed on the surface of the substrate 100 before depositing the dielectric layer 120 to avoid over-etching.

As shown in FIG. 1B, a TaN barrier layer 140 is deposited by atomic layer deposition (ALD) on the bottom and sidewalls of the via opening 130, i.e. lining the via opening 130. Generally, the thickness of the TaN layer 140 of interconnect depends on the device generation. The preferred thickness of the TaN layer 140 formed by atomic layer deposition can be 5-100 Å for 130 nm to 90 nm device node. In addition, the ALD-TaN layer 140 for copper barrier application can be deposited at temperatures of 250-300° C., fully compatible with low-k dielectric integration.

In FIG. 1C, the substrate 110 is subjected to a treatment to increase Ta/N ratio of ALD-TaN layer 140. Preferably, plasma treatment 150 is performed on ALD-TaN layer 140. More preferably, inert gas, e.g. Ar, or Ta plasma treatment can be performed on ALD-TaN layer 140 to reduce nitrogen (N) percentage of the TaN layer 140 or to increase tantalum (Ta) content thereof respectively, thereby increasing the Ta/N ratio of ALD-TaN layer 140 to form a Ta-rich ALD-TaN layer 140′.

The argon (Ar) plasma treatment in this specification denotes a plasma treatment with Ar as the major gas source for plasma generation. The Ar⁺ ions generated in a plasma chamber are directed to bombard the surface of the ALD-TaN layer 140 and break the linkage of Ta—N. The ionized tantalum is more easily recombinated with the ALD-TaN layer 140 than ionized nitrogen that may be carried away by an exhaust flow, thereby adjusting the Ta/N ration of the ALD-TaN layer 140. Other gas can be used as well to assist Ar plasma treatment efficiency, although the invention is not limited thereto.

Moreover, the tantalum (Ta) plasma treatment in this specification denotes a plasma treatment with a tantalum metal target. An inert gas, e.g. Ar, is utilized as a source gas for plasma generation. Positively charged argon ions in the plasma are directed to bombard the tantalum target as a cathode. When argon ions strike the tantalum target surface, tantalum atoms are dislodged from the target. The ejected tantalum atoms move through the plasma and strike the TaN layer 140, thereby increasing the Ta/N of the ALD-TaN layer 140. In addition, ejected tantalum atoms can also bombard the TaN layer surface and break the T-N linkage, which improves removal of the nitrogen from the ALD-TaN layer 140.

The plasma treatment can be in-situ performed in the ALD chamber if the ALD chamber is equipped with a plasma generation device. The substrate 100 can also be transferred to a physical vapor deposition (PVD) or chemical vapor deposition (CVD) chamber for the plasma treatment. The preferred operation conditions of Ar and Ta Plasma treatment can be as follow:

RF power: 0-10 W

Bias: 500-1500 W

Gas flow rate: 100-200 sccm

Pressure: 3000-6000 mtorr

The preferred time period to operate Ar plasma treatment can be 10-100 seconds. Thus, the resistivity of the ALD-TaN layer 140′ is reduced due to the increased Ta/N ratio of the ALD-TaN layer 140 by the plasma treatment.

After a Ta-rich ALD-TaN layer 140′ is formed, a Ta layer (not shown) can be optionally formed to comprise a two-layer (Ta+TaN) diffusion barrier. The Ta layer can be formed by PVD, high-density plasma chemical vapor deposition (HDPCVD) or ALD. The Ta layer can be subsequently formed in the same chamber as the plasma treatment or transferred to another chamber for process.

After the barrier layer is formed, a copper seed layer 160 is subsequently formed on the barrier layer, i.e. the treated ALD-TaN layer 140′ or the laminated layer composed of the treated ALD-TaN layer 140′ and the Ta layer. The copper seed layer 160 can be formed with CVD or PVD and is preferably uniform and free of pinholes. Preferably, the plasma treatment 150, the additional Ta layer and the copper seed layer 160 can be in-situ formed in the same PVD or CVD chamber.

In FIG. 1E, copper 162 is deposited to fill the opening 130 with electrochemical deposition (ECD). The excess copper on the surface of the dielectric layer 120 is then planarized with chemical mechanical polishing (CMP) until the surface of the dielectric layer 120 is exposed, forming a copper plug 164 as shown in FIG. 1F. Subsequent processing may include forming an etching stop layer 170 covering the surface of the dielectric layer 120 and the copper plug 164 for upper level metallization.

As a result, as shown in FIG. 1E, an interconnect structure is formed with a plasma-treated ALD-TaN layer as a barrier and a adhesion layer between the copper plug (164+160) and the dielectric layer 120, and as a conductive layer electrically connecting the underlying conductive region 110 in the substrate 110 with the upper copper plug (164+160).

Experimental Data

Herein some experiment data and drawings are provided to further illustrate the improvement that the claimed invention can achieve. However, the claimed invention should not be limited thereto.

Ta/N Ratio

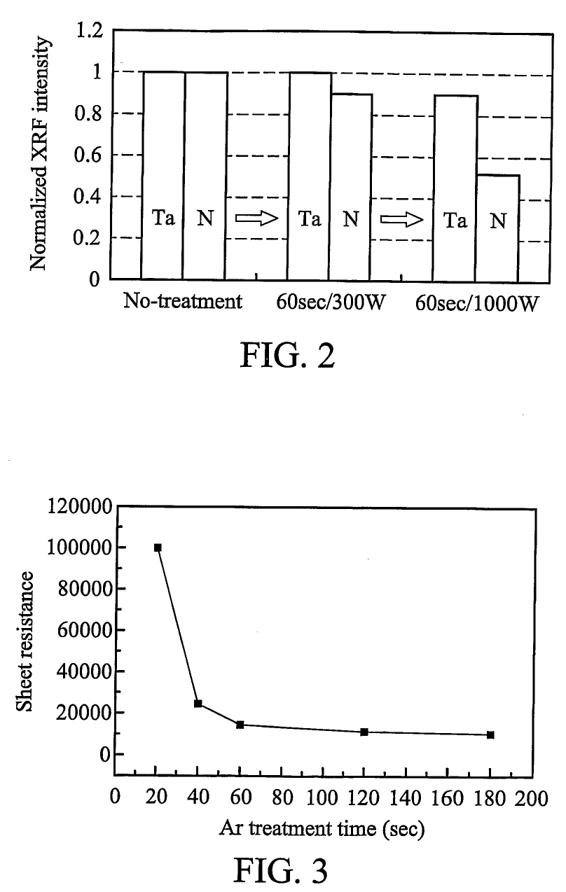

FIG. 2 shows the variation of Ta/N ratio measured by X-Ray Fluorescence (XRF) after Ar plasma treatment. The normalized XRF intensity of Ta and N of a 40 Å TaN layer formed by ALD, i.e. no additional treatment, are both 1.0, which implies the contents of Ta and N of the TaN layer are equal. However, after the 40 Å TaN layer is treated with Ar plasma at an operating power of 300 W for 60 seconds, the normalized XRF intensity of N is reduced to about 0.9 which that of Ta is still 1.0. The TA/N ratio thereof is about 1.11. If the 40 Å TaN layer is treated with Ar plasma with an elevated operation power of 1000 W for 60 seconds, the normalized XRF intensity of N and Ta are reduced to about 0.5 and 0.9 respectively. The Ta/N ratio thereof is about 1.8, much higher than no treatment. As shown in FIG. 2, the Ar plasma treatment increases the Ta/N ratio of an ALD-formed TaN layer, i.e. reducing the N content of the ALD-formed TaN layer. The variation of the Ta/N ratio depends on the operation power.

In addition, according to Auger Electron Spectroscopy (AES) testing results, the preferred Ta/N ratio of the after ALD-formed TaN layer after the Ar plasma treatment is also higher than 1.0 and the preferred Ta/N ratio is 1.2-1.3.

Resistivity

FIG. 3 shows the influence of sheet resistance with varied treatment time periods. The sheet resistance of an ALD-TaN layer treated with Ar plasma treatment for 20 seconds is between 100000 and 90000 ohms/square. However, the sheet resistance of the same ALD-TaN layer drops to about 20000 ohms/square after treatment with Ar plasma for 40 seconds. The sheet resistance of the same ALD-TaN layer decreases to about 10000 ohms/square after 60 seconds treatment and gradually to about 200 ohms/square after 180 seconds. It is evident that the sheet resistance of an ALD-TaN layer can be reduced with Ar plasma treatment. According to the data shown in FIGS. 2 and 3, it is found that the Ta/N ratio of the TaN layer can be increased, i.e. higher than 1.0, after the plasma treatment and the sheet resistance thereof is decreased accordingly.

Adhesion

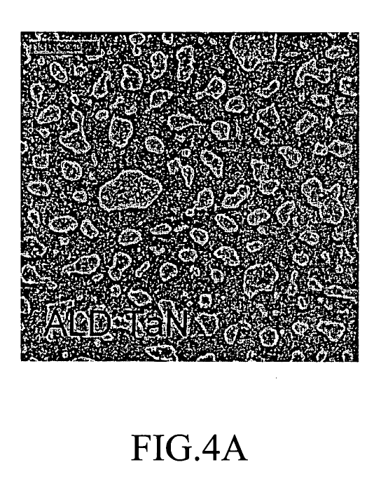

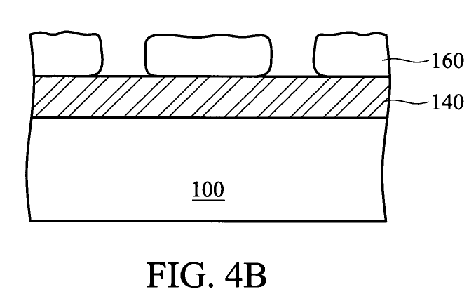

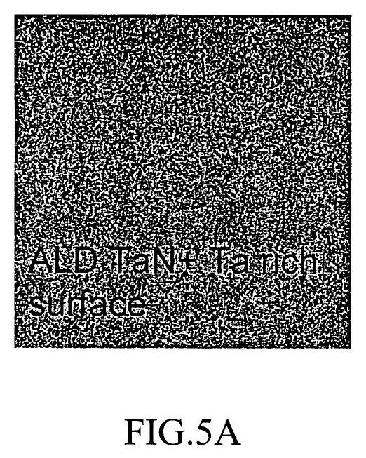

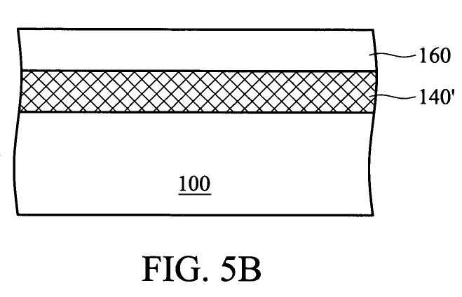

FIGS. 4A and 5A are scanning electron microscopy (SEM) photos of copper seed layers 160 deposited on a non-plasma-treated TaN layer 140 and an Ar plasma treated TaN layer 140′ respectively. The thickness of the copper seed layer is about 100 Å. FIGS. 4B and 5B are cross sections of the structures in FIGS. 4A and 5A respectively. The only difference between the two structures shown in FIG. 4A and 5A is treatment of the TaN layer with Ar plasma. After copper seed layers 160 were deposited on the non-plasma-treated ALD-TaN layer 140 and the Ar plasma treated ALD-TaN layer 140′ respectively, the two structures were subjected to about 25° C. for 10-100 seconds. The two structures were then examined with a SEM.

FIGS. 4A and 4B show, after thermal treatment, the copper seed layer 160 beading to form small knobs on the surface of the ALD-TaN layer 140, rather than a continuous barrier layer. The knob formation is known as a de-wetting phenomenon, wherein the adhesion force of copper atoms to the ALD-formed TaN layer 140 is less than the cohesion force of copper atoms themselves, resulting in low wettability. The conventional ALD-TaN layer 140 (i.e. no plasma treatment) cannot provide sufficient wettability for the subsequent copper seed layer 160 to form a continuous layer, thereby degrading the quality of copper interconnect.

FIGS. 5A and 5B show, after thermal treatment, the copper seed layer 160 maintaining continuous and uniform presence on the surface of the Ar-plasma treated ALD-TaN layer 140′ without any copper knobs formed thereon. FIG. 5A shows wettability between the Ar plasma-treated ALD-TaN layer 140′ and the copper seed layer 160 increased, providing a continuous and uniform copper seed layer 160 for subsequent copper filling. Thus, Ar plasma-treatment not only reduces the resistivity of the ALD-TaN layer, but also improves adhesion between the ALD-TaN layer and the copper seed layer.

Although the present invention has been described in its preferred embodiments, it is not intended to limit the invention to the precise embodiments disclosed herein. Those skilled in this technology can still make various alterations and modifications without departing from the scope and spirit of this invention. Therefore, the scope of the present invention shall be defined and protected by the following claims and their equivalents.

1. A method for forming an interconnect structure, comprising:
forming a dielectric layer overlying a substrate;
forming an opening in the dielectric layer;
forming a barrier layer lining the opening by atomic layer deposition (ALD);
performing a tantalum (Ta) plasma treatment on the ALD-barrier layer; and
filling the opening with a conductive layer.

2. The method of as claimed in claim 1, wherein the ALD-barrier layer is an ALD-TaN layer.

3. The method of as claimed in claim 1, wherein the plasma treatment is a plasma treatment with a tantalum metal-coating target.

4. The method of as claimed in claim 3, wherein the tantalum plasma treatment utilizes an inert gas as a source gas.

5. The method as claimed in claim 1, further comprising: forming a tantalum layer on the surface of the treated ALD-TaN layer before filling the opening with the conductive layer.

6. The method as claimed in claim 1, wherein the dielectric layer comprises a low-k material with a dielectric constant k<3.2.

7. A method for forming a barrier layer in an interconnect opening, comprising:
forming an opening in a substrate;
forming a TaN layer on the substrate and lining the opening by atomic layer deposition (ALD); and
increasing Ta/N ratio of the ALD-TaN layer by performing a tantalum plasma treatment.

8. The method as claimed in claim 7, wherein the Ta/N ratio is increased by performing a plasma treatment with a tantalum metal-coating target on the ALD-TaN layer.

9. (canceled)

10. The method as claimed in claim 8, further comprising: forming a tantalum layer with increased Ta/N ratio on the surface of the TaN layer.

11. A method for reducing resistivity of transition metallic nitride formed by atomic layer deposition (ALD), comprising:
forming a transition metallic nitride layer by atomic layer deposition (ALD); and
performing a transition metallic plasma treatment on the ALD-transition metallic nitride layer to increase transition metal-nitrogen ration thereof.

12. The method of as claimed in claim 11, wherein the plasma treatment is a plasma treatment with the same transition metal.

13. The method as claimed in claim 11, wherein the transition metallic nitride layer is a TaN layer or TiN layer.

14. A method for adjusting element ratio of a binary compound composed of a first element and a second element, formed by atomic layer deposition (ALD), comprising:
forming the binary compound layer by atomic layer deposition (ALD); and
performing a transition metallic plasma treatment on the ALD-binary compound layer to increase the first element/the second ratio thereof.

15. The method as claimed in claim 14, wherein the binary compound is TaN and the first and second elements are Ta and N respectively.

16. The method of as claimed in claim 15, wherein the plasma treatment is a plasma treatment with the first element.

17.-20. (canceled)
